(19) United States
(12) Patent Application Publication
(10) Pub. No.: US 2022/0189777 A1
(43) Pub. Date: Jun. 16, 2022

(54) FILM FORMATION METHOD AND FILM FORMATION APPARATUS

(71) Applicant: Tokyo Electron Limited, Minato-ku, Tokyo (JP)

(72) Inventors: Yumiko KAWANO, Nirasaki-shi, Yamanashi (JP); Shuji AZUMO, Nirasaki-shi, Yamanashi (JP); Hiroki MURAKAMI, Nirasaki-shi, Yamanashi (JP)

(21) Appl. No.: 17/593,166

(22) PCT Filed: Mar. 4, 2020
(86) PCT No.: PCT/JP2020/009208

§ 371 Date: Sep. 10, 2021

(30) Foreign Application Priority Data
Mar. 15, 2019 (JP) 2019-048532

(51) Int. Cl. H01L 21/285; C23C 16/455; C23C 16/44; C23C 16/18; C23C 16/52

(52) U.S. Cl. CPC H01L 21/28562; H01L 21/28568; C23C 16/52; C23C 16/4412; C23C 16/18; C23C 16/45544

(57) ABSTRACT

A film formation method includes: providing a substrate including a first region in which a first material is exposed and a second region in which a second material different from the first material is exposed; forming a target film selectively in the first region among the first region and the second region; and removing a product produced in the second region in the forming the target film by supplying ClF₃ gas to the substrate.

### TECHNICAL FIELD

The present disclosure relates to a film formation method and a film formation apparatus.

### BACKGROUND

Patent Document 1 discloses a technique of depositing a metal material on a first surface of a substrate and an insulating material on a second surface of the substrate. The first surface is a surface of a metal or a semiconductor, and the second surface has OH groups or the like. As a specific example, a technique of forming a Ru film on the first surface using the fact that Ru(EtCp)₂ does not react with Si—OH is disclosed.

### PRIOR ART DOCUMENTS

### Patent Documents

Patent Document 1: U.S. Patent Application Publication No. 2015/0299848

### SUMMARY

An aspect of the present disclosure provides a technique capable of removing a product produced in a second region and leaving a target film in the first region when a desired target film is selectively formed in the first region.

A film formation method of an aspect of the present disclosure includes: providing a substrate including a first region in which a first material is exposed and a second region in which a second material different from the first material is exposed; forming a target film selectively in the first region among the first region and the second region; and removing a product produced in the second region in the forming the target film by supplying ClF₃ gas to the substrate.

According to an aspect of the present disclosure, when a target film is formed selectively in a first region, it is possible to remove the product produced in the second region and to leave the target film in the first region.

### BRIEF DESCRIPTION OF DRAWINGS

FIG. 1 is a flowchart illustrating a film formation method according to a first embodiment.

FIGS. 2A to 2C are side views illustrating examples of states of a substrate in respective steps illustrated in FIG. 1.

FIG. 3 is a flowchart illustrating an example of formation of a Ru film using an ALD method.

FIG. 4 is a flowchart illustrating an example of removal of a product using ClF₃ gas.

FIG. 5 is a flowchart illustrating a film formation method according to a second embodiment.

FIGS. 6A to 6E are side views illustrating examples of states of a substrate in respective steps illustrated in FIG. 5.

FIG. 7 is a cross-sectional view illustrating an example of a film formation apparatus that performs the film formation method illustrated in FIG. 1 or FIG. 5.

FIGS. 8A and 8B are perspective views of states immediately before and immediately after removal of a product according to Example 1, taken using an SEM.

FIGS. 9A to 9E are perspective views of states before and after etching according to Reference Examples 1 to 4, taken using an SEM.

FIGS. 10A to 10F are perspective views of states after etching according to Reference Examples 5 to 10, taken using an SEM.

FIGS. 11A and 11B are a perspective view and a cross-sectional view of states before and after etching according to Reference Example 11, taken using an SEM.

### DETAILED DESCRIPTION

Hereinafter, embodiments of the present disclosure will be described with reference to the drawings. In each drawing, the same or corresponding components may be denoted by the same reference numerals, and a description thereof may be omitted.

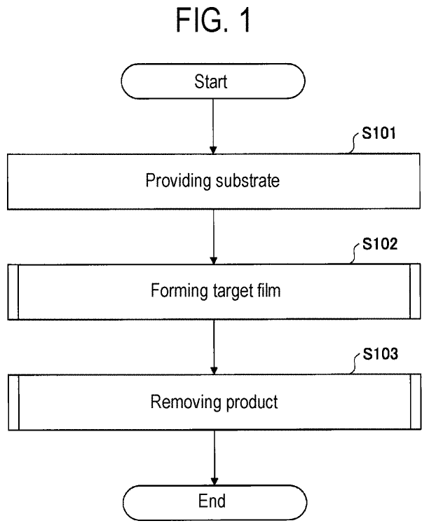

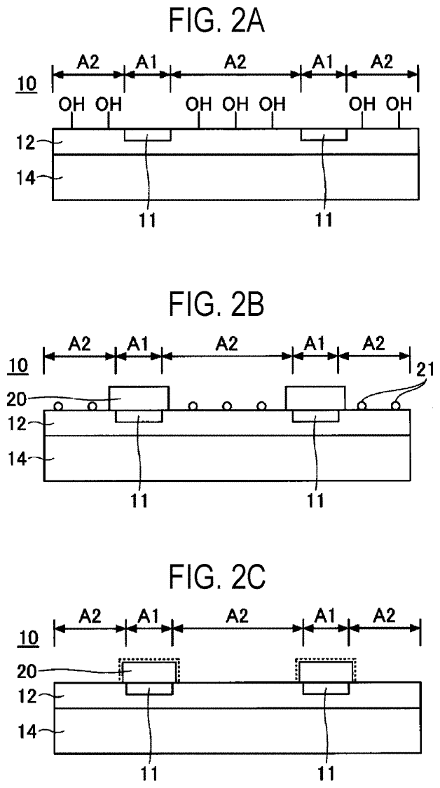

FIG. 1 is a flowchart illustrating a film formation method according to a first embodiment. FIGS. 2A to 2C are side views illustrating examples of states of a substrate in respective steps illustrated in FIG. 1. FIG. 2A illustrates the state of the substrate prepared in step S101, 2B illustrates the state of the substrate obtained in step S102, and FIG. 2C illustrates the state of the substrate after step S103. In FIG. 2C, the size of a Ru film 20 immediately before step S103 is illustrated by a broken line, and the size of the Ru film 20 immediately after step S103 is illustrated by a solid line.

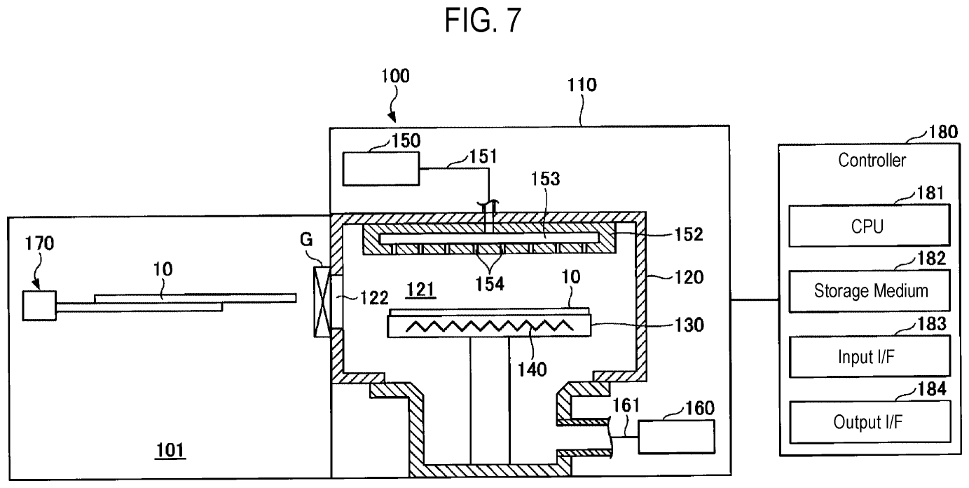

The film formation method includes step S101 of providing a substrate 10, as illustrated in FIG. 2A. The providing the substrate 10 includes, for example, carrying the substrate 10 into the processing container 120 (see FIG. 7) to be described later. The substrate 10 includes first regions A1 in which a first material is exposed and second regions A2 in which a second material different from the first material is exposed. The first regions A1 and the second regions A2 are provided on one side of the substrate 10 in the substrate thickness direction.

Although only the first regions A1 and the second regions A2 are present in FIG. 2A, a third region may be further present. The third region is a region in which a third material different from the first material and the second material is exposed. The third region may be disposed between the first regions A1 and the second regions A2, or may be disposed outside the first regions A1 and the second regions A2.

The first material is, for example, a conductive material. The conductive material is Ru in this embodiment, but may be RuO₂, Pt, Pd, or Cu. A Ru film 20 as a target film is formed on the surface of these conductive materials in step S102 to be described later. The Ru film 20 is a conductive film.

The second material is, for example, an insulating material having OH groups. The insulating material is a low dielectric constant material (a low-k material) having a dielectric constant lower than that of SiO₂ in this embodiment, but is not limited to the low-k material. Since the OH groups are generally present on the surface of the insulating material, it is possible to suppress formation of the Ru film 20 in step S102 to be described later. It is also possible to increase the number of OH groups by treating the surface of the insulating material with ozone (O₃) gas before forming the Ru film 20.

The substrate 10 has, for example, a conductive film 11 formed of the above-mentioned conductive material and an insulating film 12 formed of the above-mentioned insulating material. In the substrate 10, for example, the conductive film 11 is formed in a trench in the insulating film 12, and the conductive film 11 and the insulating film 12 are flattened through polishing. The polishing is, for example, chemical mechanical polishing (CMP).

Although the surface of the conductive film 11 and the surface of the insulating film 12 are flush with each other in FIG. 2A, the films may be displaced to be parallel to each other. That is, a step may be formed between the surface of the conductive film 11 and the surface of the insulating film 12. When the surface of the conductive film 11 is recessed with respect to the surface of the insulating film 12, the recess serves as a guide when the Ru film 20 is formed.

In addition, the substrate 10 has a base substrate 14 on which the conductive film 11 and the insulating film 12 are formed. The base substrate 14 is a semiconductor substrate such as a silicon wafer. In addition, the base substrate 14 may be, for example, a glass substrate. In addition, the substrate 10 may further include, between the base substrate 14 and the insulating film 12, a base film formed of a material different from those of the base substrate 14 and the insulating film 12.

The film formation method includes step S102 of forming a desired target film selectively in the first regions A1 among the first regions A1 and the second regions A2 as illustrated in FIG. 2B. The target film is, for example, a Ru film 20, and is formed by supplying Ru(EtCp)₂ gas and O₂ gas to the substrate 10. The formation of the Ru film 20 is performed inside the processing container 120 (see FIG. 7). When the third region is present in addition to the first regions A1 and the second regions A2, the Ru film 20 may or may not be formed in the third region.

The Ru film 20 is formed through a chemical vapor deposition (CVD) method or an atomic layer deposition (ALD) method. In the CVD method, Ru(EtCp)₂ gas and O₂ gas are simultaneously supplied to the substrate 10. In the ALD method, Ru(EtCp)₂ gas and O₂ gas are alternately supplied to the substrate 10.

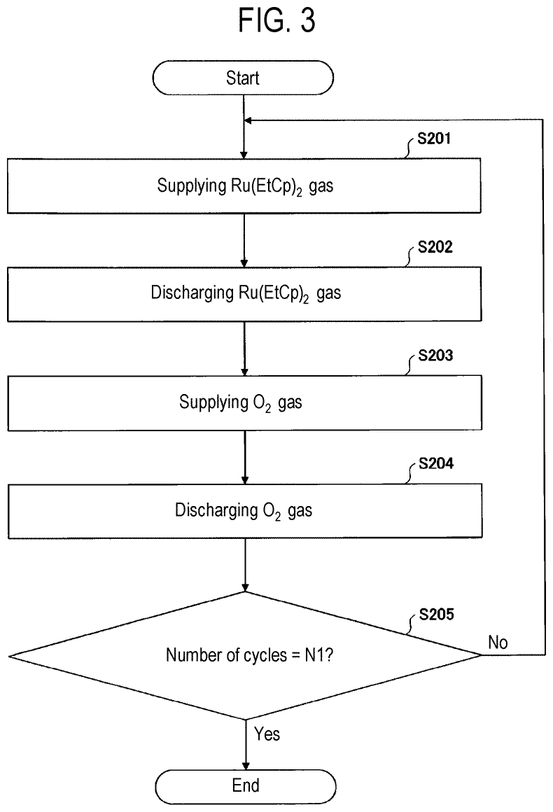

FIG. 3 is a flowchart illustrating an example of formation of a RU film using the ALD method. As illustrated in FIG. 3, the formation of a Ru film 20 (step S102) includes supply of Ru(EtCp)₂ gas (step S201), discharge of the Ru(EtCp)₂ gas (step S202), supply of O₂ gas (step S203), and discharge of the O₂ gas (step S204). In these steps S201 to S204, the pressure inside the processing container 120 is, for example, 67 Pa or higher and 667 Pa or lower (0.5 Torr or higher and 5 Torr or lower), and the temperature of the substrate 10 is, for example, 250 degrees C. or higher and 350 degrees C. or lower.

The supply of Ru(EtCp)₂ gas (step S201) includes heating a raw material container containing liquid Ru(EtCp)₂ to 60 to 100 degrees C. and supplying vaporized Ru(EtCp)₂ gas from the raw material container together with a carrier gas to the processing container 120. In addition to the Ru(EtCp)₂ gas and the carrier gas, a diluting gas for diluting the Ru(EtCp)₂ gas may also be supplied into the processing container 120. As the carrier gas and the diluting gas, an inert gas, such as argon (Ar) gas, is used. The supply of the Ru(EtCp)₂ gas (step S201) may further include exhausting the interior of the processing container 120 using a vacuum pump in order to suppress a pressure change inside the processing container 120.

The discharge of the Ru(EtCp)₂ gas (step S202) includes exhausting the interior of the processing container 120 using the vacuum pump in the state in which the supply of the Ru(EtCp)₂ gas into the processing container 120 is stopped. The discharge of the Ru(EtCp)₂ gas (step S202) may further include supplying a purge gas into the processing container 120 in order to suppress a pressure change inside the processing container 120. As the purge gas, an inert gas such as argon gas is used.

The supply of the O₂ gas (step S203) includes supplying O₂ gas into the processing container 120. In addition to the O₂ gas, a diluting gas for diluting the O₂ gas may also be supplied into the processing container 120. As the diluting gas, an inert gas such as argon (Ar) gas is used. The supply of the O₂ gas (step S203) may further include exhausting the interior of the processing container 120 using the vacuum pump in order to suppress a pressure change inside the processing container 120.

Similar to the discharge of the Ru(EtCp)₂ gas (step S202), the discharge of the O₂ gas (step S204) includes exhausting the interior of the processing container 120 using the vacuum pump in the state in which the supply of the O₂ gas into the processing container 120 is stopped. In addition, the discharge of the O₂ gas (step S204) may further include supplying a purge gas into the processing container 120 in order to suppress a pressure change inside the processing container 120. As the purge gas, an inert gas such as argon gas is used.

In the supply of the Ru(EtCp)₂ gas (step S201), the discharge of the Ru(EtCp)₂ gas (step S202), the supply of the O₂ gas (step S203), and the discharge of the O₂ gas (step S204), the total flow rate of the gases supplied into the processing container 120 may be the same. This makes it possible to further suppress a pressure change inside the processing container 120.

For the formation of the Ru film 20 (step S102), the above steps S201 to S204 are set as one cycle, and the cycle is repeatedly performed. The formation of the Ru film 20 includes step S205 of checking whether or not the number of cycles has reached the target number of times N1. The target number of times N1 is set in advance through an experiment or the like such that the thickness of the Ru film 20 reaches a target film thickness when the number of cycles reaches the target number of times N1.

When the number of cycles is less than the target number of times N1, since the thickness of the Ru film 20 has not reached the target film thickness, the above steps S201 to S204 are performed again. Meanwhile, when the number of cycles is the target number of times N1,since the film thickness of the Ru film 20 has reached the target film thickness, the current process is terminated.

Meanwhile, the Ru(EtCp)₂ gas is not adsorbed onto the surface on which OH groups are present, but is adsorbed onto the surface on which OH groups are not present. As illustrated in FIG. 2A, no OH group is in the first regions A1 and OH groups are present in the second regions A2. Therefore, as illustrated in FIG. 2B, a Ru film 20 is selectively formed in the first regions A1 among the first regions A1 and the second regions A2. As illustrated in FIG. 2B, the Ru film 20 may be formed to protrude from the first regions A1.

The Ru(EtCp)₂ gas basically is not adsorbed on the second regions A2. However, when defects are present in the second regions A2, the Ru(EtCp)₂ gas is adsorbed on the defects. The defects may include metal or damage remaining after polishing such as CMP. Since the Ru(EtCp)₂ gas is adsorbed on the defects in the second regions A2, a product 21 is also formed in an island shape in the second regions A2 as illustrated in FIG. 2B. The product 21 is formed of Ru in the same manner as the Ru film 20. Therefore, a conductive product 21 is formed in a region in which an insulating material should be exposed.

Therefore, the film formation method includes step S103 of removing the product 21 produced in the second regions A2 during the formation of the Ru film 20, as illustrated in FIG. 2C, by supplying ClF₃ gas to the substrate 10. In this step S103, ClF₃ gas is used instead of O₃ gas as the etching gas for removing the product 21.

The ClF₃ gas etches the product 21 from the surface thereof. At this time, the ClF₃ gas also etches the Ru film 20 from the surfaces thereof, but the volume change of the Ru film 20 is slower than the volume change of the product 21. This is because the specific surface area (the surface area per unit volume) of the Ru film 20 is smaller than the specific surface area of the product 21.

Compared with the O₃ gas, the ClF₃ gas is able to evenly etch the entire surface of Ru and suppress the acceleration of local etching. Therefore, the product 21 and the Ru film 20 can be etched at volume change rates according to the specific surface areas thereof, respectively. Therefore, the ClF₃ gas is able to remove the product 21 produced in the second regions A2 and leave the Ru film 20 in the first regions A1.

The ClF₃ gas removes the product 21 by chemically reacting with the product 21. The ClF₃ gas may be heated to a high temperature to promote the chemical reaction with the product 21. Further, the ClF₃ gas may be plasmatized in order to promote the chemical reaction with the product 21, but is not plasmatized in this embodiment. In this embodiment, from the viewpoint of reducing damage to the Ru film 20, the ClF₃ gas is thermally excited, rather than being plasma-excited. The thermal excitation generates Cl radicals, F radicals, or the like, and these radicals chemically react with the product 21. The removal of the product 21 is performed inside the processing container 120 (see FIG. 7).

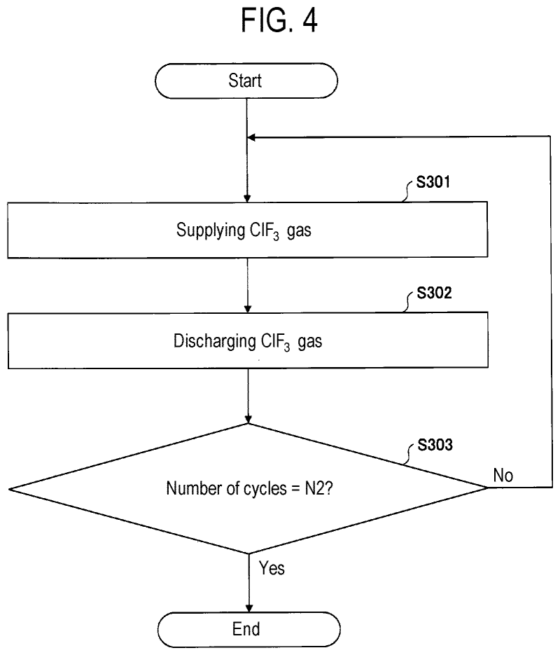

FIG. 4 is a flowchart illustrating an example of product removal using ClF₃ gas. As illustrated in FIG. 4, the removal of the product 21 (step S103) includes supply of ClF₃ gas (step S301) and the discharge of the ClF₃ gas (step S302). In these steps S301 to S302, the pressure inside the processing container 120 is, for example, 133 Pa or higher and 1,333 Pa or lower (1 Torr or higher and 10 Torr or lower), and the temperature of the substrate 10 is, for example, 150 degrees C. or higher and 250 degrees C. or lower.

The supply of the ClF₃ gas (step S301) includes supplying ClF₃ gas into the processing container 120. In addition to the ClF₃ gas, a diluting gas for diluting the ClF₃ gas may also be supplied into the processing container 120. As the diluting gas, an inert gas such as argon (Ar) gas is used. The partial pressure of the ClF₃ gas inside the processing container 120 is, for example, 67 Pa or higher and 667 Pa or lower (0.5 Torr or higher and 5 Torr or lower). The supply of the ClF₃ gas (step S301) may further include exhausting the interior of the processing container 120 using the vacuum pump in order to suppress a pressure change inside the processing container 120.

The discharge of the ClF₃ gas (step S302) includes exhausting the interior of the processing container 120 using the vacuum pump in the state in which the supply of the ClF₃ gas into the processing container 120 is stopped. The discharge of the ClF₃ gas (step S302) may further include supplying a purge gas into the processing container 120 in order to suppress a pressure change inside the processing container 120. As the purge gas, an inert gas such as argon gas is used.

The total flow rate of the gases supplied to the inside of the processing container 120 may be the same in the supply of the ClF₃ gas (step S301) and the discharge of the ClF₃ gas (step S302). This makes it possible to further suppress a pressure change inside the processing container 120.

For the removal of the product 21 (step S103), the above-mentioned steps S301 to S302 are set as one cycle, and the cycle is repeatedly performed. During one cycle, the ClF₃ gas supply time T1 is, for example, 1 second or more and 20 seconds or less, and the ClF₃ gas discharge time T2 is, for example, 1 second or more and 20 seconds or less. The one-cycle time T (T=T1+T2) is, for example, 5 seconds or more and 40 seconds or less, and the ratio of the ClF₃ gas supply time T1 to the one-cycle time T, (T1/T), is, for example, 0.3 or more and 0.7 or less.

The removal of the product 21 (step S103) includes a step S303 of checking whether or not the number of cycles has reached the target number of times N2. The target number of times N2 is set in advance through an experiment or the like such that the product 21 is removed when the number of cycles reaches the target number of times N2. The target number of times N2 is determined based on the target film thickness of the Ru film 20 (that is, the target number of times N1 in FIG. 3), and the smaller the target film thickness of the Ru film 20, the smaller the target number of times N2.

When the number of cycles is less than the target number of times N2, since a part of the product 21 remains, the above-mentioned steps S301 to S302 are performed again. Meanwhile, when the number of cycles is the target number of times N1, since the product 21 has already been removed, the current process is terminated.

The removal of the product 21 (step S103) includes alternately and repeatedly performing the supply of the ClF₃ gas (step S301) and the discharge of the ClF₃ gas (step S302), as illustrated in FIG. 4. Compared with the case in which the ClF₃ gas is continuously supplied without performing the discharge of the ClF₃ gas, it is possible to prevent the etching from being accelerated at grain boundaries of Ru, and thus a Ru film 20 having a smooth surface is obtained.

As illustrated in FIG. 1, the film formation method of this embodiment includes each of the formation of the Ru film 20 (step S102) and the removal of the product 21 (step S103) once, but the technique of the present disclosure is not limited thereto. The film formation method may include alternately and repeatedly performing the formation of the Ru film 20 and the removal of the product 21 until the film thickness of the Ru film 20 reaches the target film thickness. In this case, the target number of times N1 in FIG. 3 is determined based on, for example, the number of times the Ru film 20 is formed until the film thickness of the Ru film 20 reaches the target film thickness, and the target film thickness of the Ru film 20. In addition, as described above, the target number of times N2 in FIG. 4 is determined based on the target number of times N1 in FIG. 3 and the like.

By separately performing the formation of the Ru film 20 a plurality of times, the size of the product 21 deposited each time may be reduced. As the size of the product 21 becomes smaller, the specific surface area of the product 21 becomes smaller, which makes it possible to shorten the time required for removing the product 21. Thus, it is possible to reduce the damage to the Ru film 20 that may occur when the product 21 is removed.

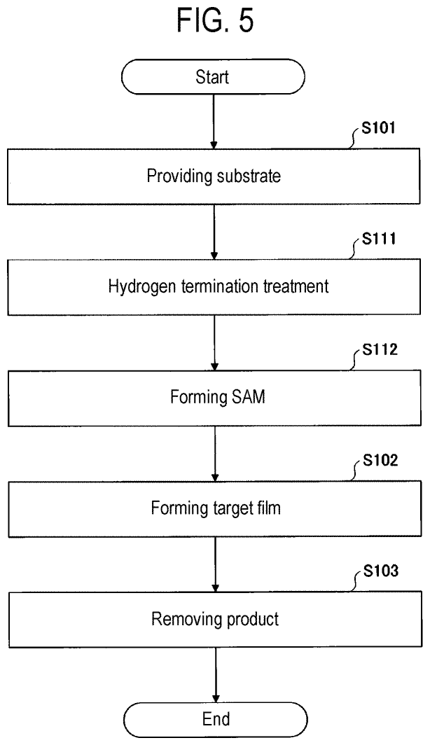

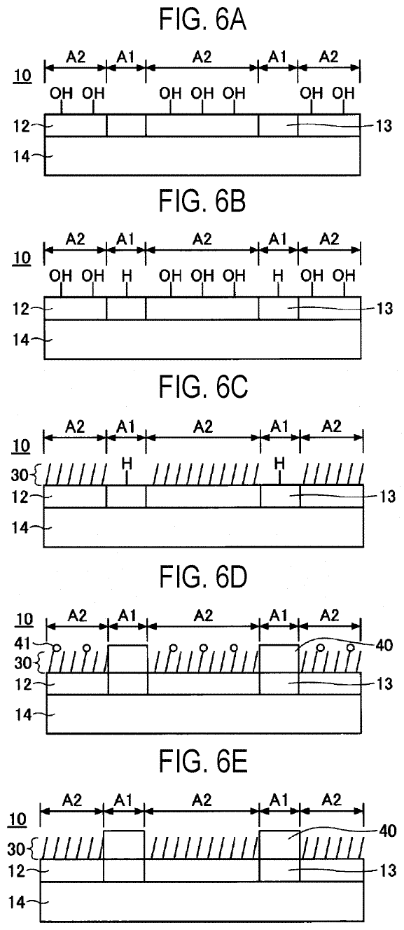

FIG. 5 is a flowchart illustrating a film formation method according to a second embodiment. FIGS. 6A to 6E are side views illustrating examples of states of a substrate in respective steps illustrated in FIG. 5. FIG. 6A illustrates the state of the substrate prepared in step S101, FIG. 6B illustrates the state of the substrate obtained in step S111, FIG. 6C illustrates the state of the substrate obtained in step S112, FIG. 6D illustrates the state of the substrate obtained in step S102, and FIG. 6E illustrates the state of the substrate obtained in step S103. Hereinafter, the differences between this embodiment and the first embodiment will be mainly described.

The film formation method includes step S101 of providing a substrate 10, as illustrated in FIG. 6A. The substrate 10 includes first regions A1 in which a first material is exposed and second regions A2 in which a second material different from the first material is exposed. Although only the first regions A1 and the second regions A2 are present in FIG. 6A, a third region may be further present.

The first material is, for example, a semiconductor, and more specifically, amorphous silicon (a-Si). The a-Si may or may not contain a dopant. Polycrystalline silicon or the like may be used instead of the amorphous silicon. In addition, a metal may be used as the first material. Since no OH group is present on the surface of these materials, the formation of a self-assembled monolayer (SAM) 30 can be suppressed in step S112 to be described later.

The second material is, for example, an insulating material having OH groups. The insulating material is silicon oxide in this embodiment, but is not limited to silicon oxide. Since OH groups are generally present on the surface of an insulating material, the SAM 30 is formed in step S112 to be described later. It is also possible to increase the number of OH groups by treating the surface of the insulating material with ozone (O₃) gas before forming the SAM 30.

The substrate 10 has, for example, a semiconductor film 13 formed of the above-mentioned semiconductor and an insulating film 12 formed of the above-mentioned insulating material. A metal film may be formed instead of the semiconductor film 13. On the surface of the semiconductor film 13 (or the metal film), an oxide film is naturally formed over time in the atmosphere. In that case, the oxide film is removed before the formation of the SAM 30 (step S112) to be described later.

In addition, the substrate 10 has a base substrate 14 on which the semiconductor film 13 and the insulating film 12 are formed. The base substrate 14 is a semiconductor substrate such as a silicon wafer. In addition, the base substrate 14 may be, for example, a glass substrate.

In addition, the substrate 10 may further include, between the base substrate 14 and the semiconductor film 13, a base film formed of a material different from those of the base substrate 14 and the semiconductor film 13. Similarly, the substrate 10 may further include, between the base substrate 14 and the insulating film 12, a base film formed of a material different from those of the base substrate 14 and the insulating film 12.

The film formation method includes step S111 of performing hydrogen termination treatment to the first material as illustrated in FIG. 6B. The hydrogen termination treatment is treatment for bonding hydrogen to uncoupled hands (dangling bonds). Through the hydrogen termination treatment of the first material, the formation of the SAM30 in the first regions A1 can be further suppressed in step S112 to be described later. Even after the hydrogen termination treatment of the first material, OH groups are present on the surface of the second material. Therefore, in step S112 to be described later, the SAM 30 is formed in the second regions A2.

The hydrogen termination treatment is performed, for example, by supplying hydrogen (H₂) gas to the substrate 10. The hydrogen termination treatment may also serve as treatment for reducing and removing an oxide film produced by the surface oxidation of the semiconductor film 13 (or a metal film). The hydrogen gas may be heated to a high temperature in order to promote the chemical reaction. In addition, the hydrogen gas may be plasmatized in order to promote the chemical reaction. The hydrogen termination treatment is dry treatment in this embodiment, but may be wet treatment. For example, the hydrogen termination treatment may be performed by immersing the substrate 10 in a dilute hydrofluoric acid.

The film formation method includes step S112 of forming an SAM 30 selectively in the second regions A2 among the first regions A1 and the second regions A2, as illustrated in FIG. 6C, by supplying a silane-based compound gas to the substrate 10. The SAM 30 is formed when a silane compound is chemisorbed onto OH groups, and inhibits the formation of a conductive film 40 as a target film to be described later. When a third region is present in addition to the first regions A1 and the second regions A2, the SAM 30 may or may not be formed in the third region.

The silane compound is, for example, a compound represented by a general formula R—SiH₃₋ₓClₓ (x=1, 2, 3) or a compound represented by R′—Si (O—R)₃ (a silane coupling agent). Here, R and R′ are functional groups such as an alkyl group or a group obtained by substituting at least a part of hydrogen of the alkyl group with fluorine. The terminal groups of the functional groups may be either CH-based or CF-based. In addition, O—R is a hydrolyzable functional group such as a methoxy group or an ethoxy group.

The silane compound, which is a material of the SAM30, is chemisorbed onto the surface having OH groups. Thus, the silane compound is selectively chemisorbed onto the second regions A2 among the first regions A1 and the second regions A2. Therefore, the SAM 30 is formed selectively in the second regions A2. The silane compound is not chemisorbed onto the surface subjected to hydrogen termination treatment. Thus, the silane compound is selectively chemisorbed by the second regions A2 among the first regions A1 and the second regions A2. Therefore, the SAM 30 is selectively formed by the second regions A2.

As illustrated in FIG. 6D, the film formation method includes a step S102 of selectively forming a conductive film 40 as a target film in the first regions A1 among the first regions A1 and the second regions A2 using the SAM 30 formed in the second regions A2. Since the SAM 30 inhibits the formation of the conductive film 40, the conductive film 40 is selectively formed in the first regions A1.

The conductive film 40 is formed through, for example, a CVD method or an ALD method. The conductive film 40 may be laminated on the semiconductor film 13, which is originally present in the first regions A1. The semiconductor film 13 may contain a dopant and may be given conductivity. The conductive film 40 may be laminated on the conductive semiconductor film 13. The material of the conductive film 40 is not particularly limited, but is, for example, a titanium nitride. Hereinafter, the titanium nitride is also referred to as “TiN” regardless of the composition ratio of nitrogen and titanium.

When a TiN film is formed as the conductive film 40 through the ALD method, a Ti-containing gas, such as tetrakisdimethylaminotitanium (TDMA: Ti[N(CH₃)₂]₄) gas or titanium tetrachloride (TiCl₄) gas, and a nitriding gas such as ammonia (NH₃) gas, are alternately supplied to the substrate 10. In addition to the Ti-containing gas and the nitriding gas, a reforming gas such as hydrogen (H₂) gas may be supplied to the substrate 10. These processing gases may be plasmatized to facilitate the chemical reaction. These processing gases may be heated to facilitate the chemical reaction.

Since the SAM 30 inhibits the formation of the conductive film 40, the conductive film 40 is selectively formed in the first regions A1 among the first regions A1 and the second regions A2. However, since the gas that is the material of the conductive film 40 is slightly adsorbed onto the SAM 30, a product 41 is also deposited in the second regions A2 in an island shape, as illustrated in FIG. 6D. The product 41 is formed of the same material as the conductive film 40, for example, TiN.

Therefore, the film formation method includes step S103 of removing the product 41 produced in the second regions A2 during the formation of the conductive film 40, as illustrated in FIG. 6E, by supplying ClF₃ gas to the substrate 10. The removal of the product 41 is performed in the same manner as the removal of the product 21 in the first embodiment. Therefore, it is possible to remove the product 41 produced in the second regions A2 and to leave the conductive film 40 in the first regions A1.

In addition, the ClF₃ gas can not only remove the product 41, but also thin or remove the SAM 30. Lift-off of product 41 can be performed by thinning or removing the SAM 30.

TiN is more easily etched by ClF₃ gas than Ru. In order to suppress the local acceleration of etching, the removal of the product 41 may be performed under different conditions from the removal of the product 21. Specifically, in order to make the etching of the TiN gentle, the temperature of the substrate 10 is low, the partial pressure of the ClF₃ gas is low, and the ratio of the ClF₃ gas supply time T1 to the one-cycle time T (T=T1+T2), (T1/T), is small.

For example, in the supply of the ClF₃ gas (step S301) and the discharge of the ClF₃ gas (step S302), the temperature of the substrate 10 is, for example, 70 degrees C. or higher and 150 degrees C. or lower. In addition, in the supply of the ClF₃ gas (step S301), the partial pressure of the ClF₃ gas inside the processing container 120 is, for example, 1.3 Pa or higher and 27 Pa or lower (0.01 Torr or higher and 0.2 Torr or lower). During one cycle, the ClF₃ gas supply time T1 is, for example, 1 second or more and 5 seconds or less, and the ClF₃ gas discharge time T2 is, for example, 3 second or more and 20 seconds or less. The one-cycle time T (T=T1+T2) is, for example, 4 seconds or more and 25 seconds or less, and the ratio of the ClF₃ gas supply time T1 to the one-cycle time T, (T1/T), is, for example, 0.1 or more and 0.5 or less.

The removal of the product 41 (step S103) includes alternately and repeatedly performing the supply of the ClF₃ gas (step S301) and the discharge of the ClF₃ gas (step S302), as illustrated in FIG. 4. Compared with the case in which the ClF₃ gas is continuously supplied without performing the discharge of the ClF₃ gas, it is possible to prevent the etching from being accelerated at grain boundaries of TiN, and thus a conductive film 40 having a smooth surface is obtained.

As illustrated in FIG. 5, the film formation method of this embodiment includes each of the formation of the conductive film 40 (step S102) and the removal of the product 41 (step S103) once, but the technique of the present disclosure is not limited thereto. The film formation method may include alternately and repeatedly performing the formation of the conductive film 40 and the removal of the product 41 until the film thickness of the conductive film 40 reaches the target film thickness. In this case, the target number of times N1 in FIG. 3 is determined based on, for example, the number of times the conductive film 40 is formed until the film thickness of the conductive film 40 reaches the target film thickness, and the target film thickness of the conductive film 40. In addition, as described above, the target number of times N2 in FIG. 4 is determined based on the target number of times N1 in FIG. 3 and the like.

By separately performing the formation of the Ru film 40 a plurality of times, the size of the product 41 deposited each time may be reduced. As the size of the product 41 becomes smaller, the specific surface area of the product 41 becomes smaller, which makes it possible to shorten the time required for removing the product 41. Thus, it is possible to reduce the damage to the conductive film 40 that may occur when the product 41 is removed.

FIG. 7 is a cross-sectional view illustrating an example of a film formation apparatus that performs the film formation method illustrated in FIG. 1 or FIG. 5. The film formation apparatus 100 includes a processing unit 110, a transfer apparatus 170, and a controller 180. The processing unit 110 includes a processing container 120, a substrate holder 130, a heater 140, a gas supplier 150, and a gas discharger 160.

Although only one processing unit 110 is illustrated in FIG. 7, a plurality of processing units 110 may be provided. The plurality of processing units 110 form a so-called multi-chamber system. The plurality of processing units 110 are arranged to surround a vacuum transfer chamber 101. The vacuum transfer chamber 101 is exhausted by a vacuum pump and is maintained at a preset degree of vacuum. In the vacuum transfer chamber 101, the transfer apparatus 170 is disposed to be movable in the vertical direction and the horizontal direction and to be rotatable around the vertical axis. The transfer apparatus 170 transfers substrates 10 to a plurality of processing containers 120. The processing chamber 121 inside the processing container 120 and the vacuum transfer chamber 101 communicate with each other when the pressures therein are both lower than the atmospheric pressure, and carry-in/out of a substrate 10 is performed therebetween. Unlike the case in which an atmospheric transfer chamber is provided instead of the vacuum transfer chamber 101, it is possible to prevent air from flowing from the atmospheric transfer chamber into the inside of the processing chamber 121 when a substrate 10 is carried in and out. It is possible to reduce the waiting time for lowering the pressure in the processing chamber 121, which makes it possible to improve the processing rate of the substrate 10.

The processing container 120 has a carry-in/out port 122 through which the substrate 10 passes. The carry-in/out port 122 is provided with a gate G that opens/closes the carry-in/out port 122. The gate G basically closes the carry-in/out port 122, and opens the carry-in/out port 122 when the substrate 10 passes through the carry-in/out port 122. When the carry-in/out port 122 is opened, the processing chamber 121 inside the processing container 120 and the vacuum transfer chamber 101 communicate with each other. Before opening the carry-in/out port 122, both the processing chamber 121 and the vacuum transfer chamber 101 are exhausted by a vacuum pump or the like and maintained at a preset pressure.

The substrate holder 130 holds the substrate 10 inside the processing container 120. The substrate holder 130 holds the substrate 10 horizontally from below with the surface of the substrate 10 exposed to the processing gas facing upwards. The substrate holder 130 is a single-wafer type and holds one substrate 10. The substrate holder 130 may be a batch type, or may hold a plurality of substrates 10 at the same time. The batch-type substrate holder 130 may hold a plurality of substrates 10 at intervals in the vertical direction or at intervals in the horizontal direction.

The heater 140 heats the substrate 10 held by the substrate holder 130. The heater 140 is, for example, an electric heater, and generates heat when electric power is supplied thereto. The heater 140 is embedded in, for example, the substrate holder 130 and heats the substrate holder 130 to heat the substrate 10 to a desired temperature. The heater 140 may include a lamp configured to heat the substrate holder 130 through a quartz window. In this case, an inert gas such as argon gas may be supplied to a space between the substrate holder 130 and the quartz window in order to prevent the quartz window from becoming opaque due to deposits. In addition, the heater 140 may heat the substrate 10 disposed inside the processing container 120 from the outside of the processing container 120.

The processing unit 110 may further include a cooler configured to cool the substrate 10 in addition to the heater 140 configured to heat the substrate 10. Not only can the temperature of the substrate 10 be raised at high speed, but the temperature of the substrate 10 can be lowered at high speed. Meanwhile, when the processing of the substrate 10 is performed at room temperature, the processing unit 110 does not have to include the heater 140 and the cooler.

The gas supplier 150 supplies preset processing gases to the substrate 10. The processing gases are prepared for, for example, respective steps S102 and S103 (or steps S111, S112, S102, and S103). These steps may be performed inside different processing containers 120, respectively, or two or more of any combinations may be performed continuously inside the same processing container 120. In the latter case, the gas supplier 150 supplies a plurality of types of processing gases to the substrate 10 in a preset order according to the order of the steps.

The gas supplier 150 is connected to the processing container 120 via, for example, a gas supply pipe 151. The gas supplier 150 includes processing gas supply sources, individual pipes individually extending from respective supply sources to the gas supply pipe 151, an opening/closing valve provided in the middle of each of the individual pipes, and a flow rate controller provided in the middle of each of the individual pipes. When the opening/closing valve opens the individual pipe, the processing gas is supplied from the supply source thereof to the gas supply pipe 151. The supply amount of the processing gas is controlled by the flow rate controller. Meanwhile, when the opening/closing valve closes the individual pipe, the supply of the processing gas from the supply source thereof to the gas supply pipe 151 is stopped.

The gas supply pipe 151 supplies the processing gas supplied from the gas supplier 150 to the interior of the processing container 120, for example, the shower head 152. The shower head 152 is provided above the substrate holder 130. The shower head 152 has a space 153 therein, and ejects the processing gas stored in the space 153 vertically downwards from a large number of gas ejection holes 154. A shower-like processing gas is supplied to the substrate 10.

The gas discharger 160 discharges gas from the interior of the processing container 120. The gas discharger 160 is connected to the processing container 120 via an exhaust pipe 161. The gas discharger 160 includes an exhaust source such as a vacuum pump, and a pressure controller. When the exhaust source is operated, gas is discharged from the interior of the processing container 120. The pressure inside the processing container 120 is controlled by a pressure controller.

The controller 180 is constituted with, for example, a computer, and includes a central processing unit (CPU) 181 and a storage medium 182 such as a memory. The storage medium 182 stores a program for controlling various processes executed in the film formation apparatus 100. The controller 180 controls the operation of the film formation apparatus 100 by causing the CPU 181 to execute the program stored in the storage medium 182. The controller 180 includes an input interface 183 and an output interface 184. The controller 180 receives a signal from the outside using the input interface 183 and transmits a signal to the outside using the output interface 184.

The controller 180 controls the heater 140, the gas supplier 150, the gas discharger 160, and the transfer apparatus 170 so as to perform the film formation method illustrated in FIG. 1 or FIG. 5. The controller 180 also controls the gate G.

### EXAMPLE 1

In Example 1, the substrate 10 illustrated in FIG. 2A was prepared. The prepared substrate 10 had a conductive film 11 made of Ru formed in trenches in an insulating film 12 made of a low-k material, and the conductive film 11 and the insulating film 12 were flattened through CMP.

Next, the formation of the Ru film 20 (step S102) was performed through the ALD method illustrated in FIG. 3. In steps S201 to S204 illustrated in FIG. 3, the pressure inside the processing container 120 was 267 Pa (2 Torr), and the temperature of the substrate 10 was 320 degrees C. In the supply of the Ru(EtCp)₂ gas (step S201), the total flow rate of the Ru(EtCp)₂ gas and argon gas as a carrier gas was 150 sccm, and the flow rate of the argon gas as a diluting gas was 250 sccm. In the discharge of the Ru(EtCp)₂ gas (step S202), the flow rate of argon gas as a purge gas, was 400 sccm. In the supply of the O₂ gas (step S203), the flow rate of the O₂ gas was 180 sccm, and the flow rate of argon gas as a diluting gas was 220 sccm. In the discharge of the O₂ gas (step S204), the flow rate of argon gas as a purge gas was 400 sccm. During one cycle, the Ru(EtCp)₂ gas supply time was 5 seconds, the Ru(EtCp)₂ gas discharge time was 5 seconds, the O₂ gas supply time was 5 seconds, and the O₂ gas discharge time was 5 seconds. That is, the time of one cycle was 20 seconds. The target number of cycles N1 was 120.

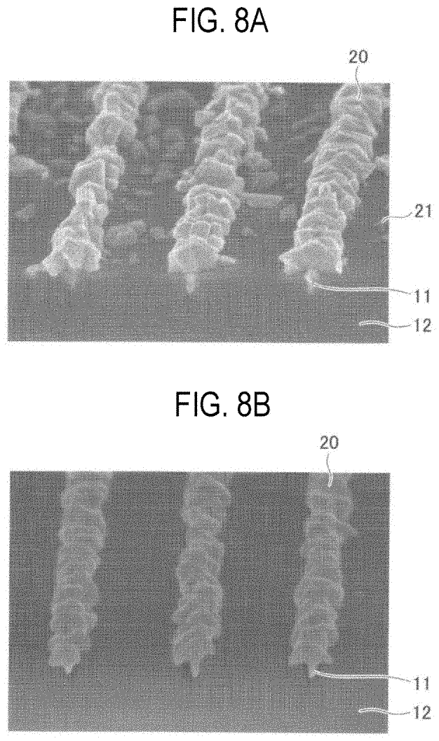

FIG. 8A is a perspective view of the state immediately before the removal of the product according to Example 1 taken using a scanning electron microscope (SEM). Since the Ru(EtCp)₂ gas is selectively adsorbed on the Ru of the Ru and the low-k materials, a Ru film 20 is formed on the conductive film 11, as illustrated in FIG. 8A. The Ru film 20 was formed to protrude from the conductive film 11. During the formation of the Ru film 20, a small product 21 was formed on the exposed surfaces of the insulating film 12.

Next, the removal of the product 21 (step S103) was performed through the method illustrated in FIG. 4. In steps S301 to S302 illustrated in FIG. 4, the pressure inside the processing container 120 was 600 Pa (4.5 Torr), and the temperature of the substrate 10 was 250 degrees C. In the supply of the ClF₃ gas (step S301), the flow rate of the ClF₃ gas was 400 sccm, the flow rate of argon gas as a diluting gas was 400 sccm, and the partial pressure of the ClF₃ gas was 300 Pa (2.25 Torr). In the discharge of the ClF₃ gas (step S302), the flow rate of argon gas as a purge gas was 800 sccm. During one cycle, the ClF₃ gas supply time T1 was 10 seconds, and the ClF₃ gas discharge time T2 was 10 seconds. The one-cycle time T (T=T1+T2) was 20 seconds, and the ratio of the ClF₃ gas supply time T1 to the one-cycle time T, (T1/T), was 0.5. The target number of cycles N2 was 6.

FIG. 8B is a perspective view of the state immediately after the removal of the product according to Example 1 taken using an SEM. By supplying the ClF₃ gas to the substrate 10, it was possible to remove the product 21 and to leave the Ru film 20, as illustrated in FIG. 8B. In addition, no damage to the extent that could be discerned in the SEM photograph was observed in the Ru film 20.

### REFERENCE EXAMPLES 1 TO 4

In Reference Examples 1 to 4, substrates in each of which a Ru film 20 having a film thickness of 24.8 nm was formed on the entire surface of a single crystal silicon substrate as the base substrate 14 using a CVD method were prepared, and the Ru films were etched using ClF₃ gas under the same conditions, except for the conditions shown in Table 1. Table 1 shows the etching conditions, the film thicknesses of the Ru films 20 after etching, and the etching rates of the Ru films 20 collectively.

TABLE 1

| | Reference | Reference | Reference | Reference |
|---|---|---|---|---|
| | Example 1 | Example 2 | Example 3 | Example 4 |
| Substrate temperature | 150 | 200 | 250 | 250 |
| (degrees C.) | | | | |
| Total pressure (Pa) | 600 | 600 | 600 | 600 |
| Flow rate of ClF₃ | 400 | 400 | 400 | 200 |
| gas (sccm) | | | | |
| Flow rate of diluting | 400 | 400 | 400 | 600 |
| gas (sccm) | | | | |
| Partial pressure of ClF₃ | 300 | 300 | 300 | 150 |
| gas (Pa) | | | | |
| T1 (sec) | 10 | 10 | 10 | 5 |
| T2 (sec) | 10 | 10 | 10 | 5 |
| N2 | 10 | 10 | 10 | 10 |
| Film thickness after | 23.8 | 15.9 | 10.4 | 19.9 |
| etching (nm) | | | | |
| Etching rate (nm/cycle) | 0.10 | 0.89 | 1.44 | 0.49 |

As is clear from Table 1, it can be seen that the higher the temperature of the substrate and the higher the partial pressure of the ClF₃ gas when the ClF₃ gas is supplied, the faster the etching rate.

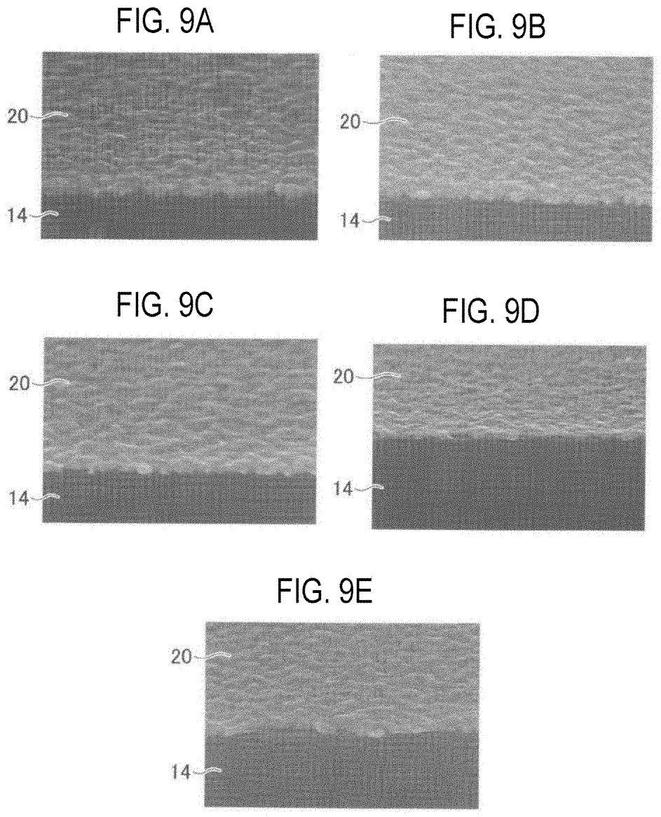

FIGS. 9A to 9E illustrates perspective views of the states before and after etching according to Reference Examples 1 to 4 taken using an SEM. FIG. 9A illustrates the state before etching according to Reference Example 1, FIG. 9B illustrates the state after etching according to Reference Example 1, FIG. 9C illustrates the state after etching according to Reference Example 2, FIG. 9D illustrates the state after etching according to Reference Example 3, and FIG. 9E illustrates the state after etching according to Reference Example 4. The states before etching according to Reference Examples 2 to 4 are the same as the state before etching according to Reference Example 1 illustrated in FIG. 9A, and thus the illustration thereof is omitted.

As is clear from FIGS. 9A to 9E, the ClF₃ gas was able to evenly etch the entire surfaces of the Ru films 20, and was able to suppress the acceleration of local etching. The surfaces of the Ru films 20 after etching were smooth.

As an example, the surface roughness Rq of the Ru film 20 after alternately and repeatedly performing the supply of the ClF₃ gas (step S301) and the discharge of the ClF₃ gas (step S302) was 0.79 nm. Meanwhile, the surface roughness Rq of the Ru film 20 after etching under the same conditions, except that the supply of the ClF₃ gas was continued without performing the discharge of the ClF₃ gas, was 1.10 nm. It was found that the smaller the Rq, the shorter the period of recess and projection on the surface and the smoother the surface.

Therefore, it was found that the Ru film 20 having a smooth surface can be obtained by repeating the supply and discharge of the ClF₃ gas.

### REFERENCE EXAMPLES 5 TO 10

In Reference Examples 5 to 10, similarly to Reference Examples 1 to 4, substrates in each of which a Ru film 20 having a film thickness of 24.8 nm was formed on the entire surface of a single crystal silicon substrate as the base substrate 14 through a CVD method were prepared. The Ru films 20 were etched using O₃ gas under the same conditions except for the conditions shown in Table 2. The etching conditions are shown in Table 2 collectively.

TABLE 2

| | Reference | Reference | Reference | Reference | Reference | Reference |
|---|---|---|---|---|---|---|
| | Example 5 | Example 6 | Example 7 | Example 8 | Example 9 | Example 10 |
| Substrate | 200 | 210 | 210 | 210 | 250 | 250 |
| temperature | | | | | | |
| (degrees C.) | | | | | | |
| Total pressure (Pa) | 133 | 133 | 133 | 67 | 133 | 133 |
| Flow rate of mixed | 500 | 500 | 1000 | 500 | 500 | 500 |
| gas (sccm) | | | | | | |
| Concentration of O₃ | 250 | 250 | 250 | 250 | 250 | 250 |
| gas (g/m³) | | | | | | |
| T1 (sec) | 1800 | 1800 | 1800 | 1800 | 1800 | 1800 |
| T2 (sec) | 0 | 0 | 0 | 0 | 0 | 0 |
| N2 | 1 | 1 | 1 | 1 | 1 | 1 |

The O₃ gas was generated from O₂ gas, and a mixed gas of the O₂ gas and the O₃ gas was supplied into the processing container 120. The O₃ gas concentration in the mixed gas was 250 g/m³ as shown in Table 2. During the etching of the Ru films 20, the mixed gas was continuously supplied, and the mixed gas was not discharged.

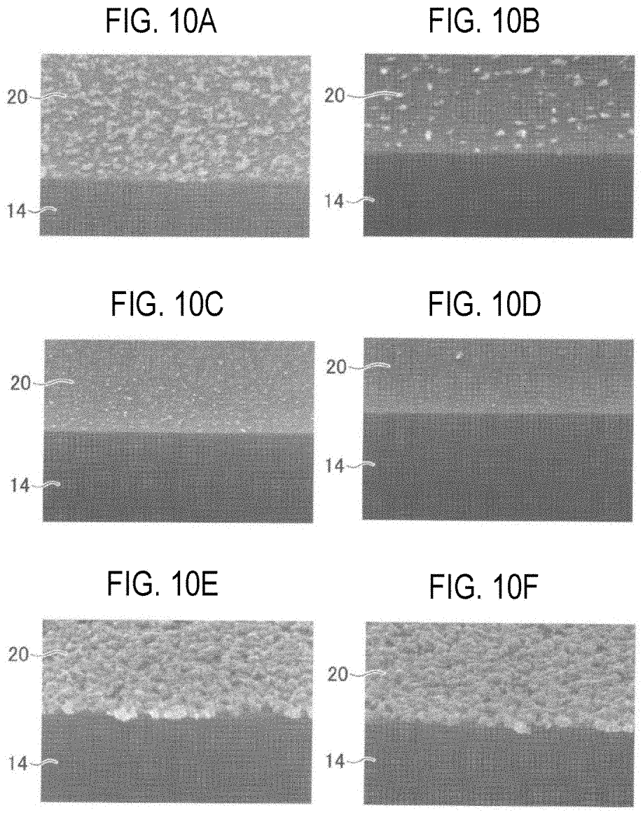

FIGS. 10A to 10F illustrate perspective views of the states after etching according to Reference Examples 5 to 10 taken using an SEM. FIG. 10A illustrates the state after etching according to Reference Example 5, FIG. 10B illustrates the state after etching according to Reference Example 6, FIG. 10C illustrates the state after etching according to Reference Example 7 and the state after etching according to Reference Example 8, FIG. 10E illustrates the state after etching according to Reference Example 9, and FIG. 10F illustrates the state after etching according to Reference Example 10. The states before etching according to Reference Examples 5 to 10 are the same as the state before etching according to Reference Example 1 illustrated in FIG. 9A, and thus the illustration thereof is omitted.

As is clear from FIGS. 10A to 10F, it can be seen that the O₃ gas etches the entire surfaces of the Ru films 20 unevenly and locally etches the Ru films 20. Therefore, it is thought that, unlike the ClF₃ gas, since the O₃ gas is not able to etch each of the product 21 and the Ru film 20 at a volume change rate corresponding to the specific surface area thereof, the Ru film 20 is also damaged when the product 21 is removed.

### REFERENCE EXAMPLE 11

In Reference Example 11, a substrate in which a TiN film as the conductive film 40 was formed on the entire surface of a single crystal silicon substrate as the base substrate 14 through the ALD method was prepared, and the TiN film was etched through the method illustrated in FIG. 4. In steps S301 to S302 illustrated in FIG. 4, the pressure inside the processing container 120 was 533 Pa (4 Ton), and the temperature of the substrate was 100 degrees C. In the supply of the ClF₃ gas (step S301), the flow rate of the ClF₃ gas was 20 sccm, the flow rate of nitrogen gas as a diluting gas was 2,000 sccm, and the partial pressure of the ClF₃ gas was 5 Pa (0.04 Torr). In the discharge of the ClF₃ gas (step S302), the flow rate of nitrogen gas as a purge gas was 2,020 sccm. During one cycle, the ClF₃ gas supply time T1 was 2 seconds and the ClF₃ gas discharge time T2 was 5 seconds. That is, the one-cycle time T (T=T1+T2) was 7 seconds, and the ratio of the ClF₃ gas supply time T1 to the one-cycle time T, (T1/T), was 0.29. The target number of cycles N2 was 5.

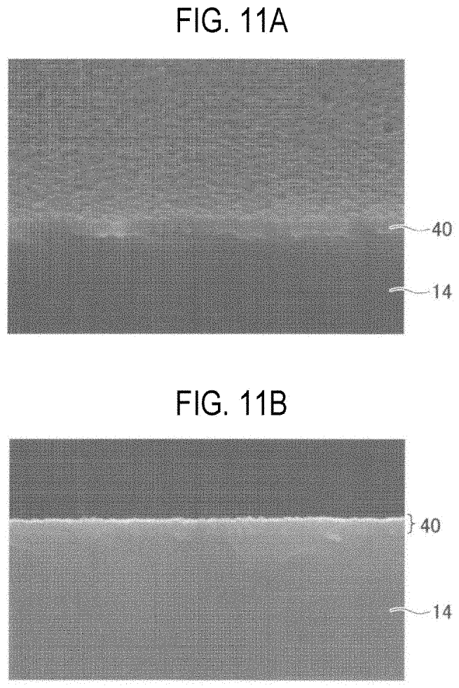

FIG. 11A is a perspective view of the state before etching according to Reference Example 11 taken using an SEM. FIG. 11B is a cross-sectional view of the state after etching according to Reference Example 11, taken using an SEM. As is clear from FIGS. 11A and 11B, the ClF₃ gas was able to evenly etch the entire surface of the TiN film as the conductive film 40, and was able to suppress the acceleration of local etching. The surface of the TiN film after etching was smooth.

Although the embodiments of the film formation method and the film formation apparatus according to the present disclosure have been described above, the present disclosure is not limited to the above-described embodiments or the like. Various changes, modifications, substitutions, additions, deletions, and combinations can be made within the scope of the claims. Of course, these also fall within the technical scope of the present disclosure.

This application claims priority based on Japanese Patent Application No. 2019-048532 filed with the Japan Patent Office on Mar. 15, 2019, and the entire disclosure of Japanese Patent Application No. 2019-048532 is incorporated herein in its entirety by reference.

### EXPLANATION OF REFERENCE NUMERALS

10: substrate, 11: conductive film, 12: insulating film, 14: base substrate, 20: Ru film, 21: product, 30: self-assembled monolayer (SAM), 40: conductive film, 41: product, 100: film formation apparatus, 110: processing unit, 120: processing container, 130: substrate holder, 140: heater, 150: gas supplier, 160: gas discharger, 170: transfer apparatus, 180: controller

1-7. (canceled)

8. A film formation method comprising:
providing a substrate including a first region in which a first material is exposed and a second region in which a second material different from the first material is exposed;
forming a target film selectively in the first region among the first region and the second region; and
removing a product produced in the second region in the forming the target film by supplying ClF₃ gas to the substrate.

9. The film formation method of claim 8, wherein the first material is a conductive material selected from the group consisting of Ru, RuO₂, Pt, Pd, and Cu,
the second material is an insulating material having an OH group, and
in the forming the target film, a Ru film is formed as the target film by supplying Ru(EtCp)₂ gas and O₂ gas to the substrate.

10. The film formation method of claim 9, wherein, in the removing the product, supplying the ClF₃ gas into an interior of a processing container in which the substrate is accommodated and discharging the ClF₃ gas from the interior of the processing container in a state of stopping the supplying the ClF₃ gas into the interior of the processing container are alternately and repeatedly performed.

11. The film formation method of claim 10, wherein the forming the target film and the removing the product are alternately repeated until a thickness of the target film reaches a target film thickness.

12. The film formation method of claim 8, wherein the first material is a metal or a semiconductor,
the second material is an insulating material having an OH group,
the film formation method further comprises forming a self-assembled monolayer selectively in the second region among the first region and the second region, and
in the forming the target film, the target film is formed in the first region among the first region and the second region using the self-assembled monolayer formed in the second region.

13. The film formation method of claim 12, further comprising:
performing hydrogen termination treatment to the first material before forming the self-assembled monolayer.

14. The film formation method of claim 8, wherein, in the removing the product, supplying the ClF₃ gas into an interior of a processing container in which the substrate is accommodated and discharging the ClF₃ gas from the interior of the processing container in a state of stopping the supplying the ClF₃ gas into the interior of the processing container are alternately and repeatedly performed.

15. The film formation method of claim 8, wherein the forming the target film and the removing the product are alternately repeated until a thickness of the target film reaches a target film thickness.

16. A film formation apparatus comprising:
a processing container;
a substrate holder configured to hold the substrate inside the processing container;
a heater configured to heat the substrate held by the substrate holder;
a gas supplier configured to supply a gas into an interior of the processing container;
a gas discharger configured to discharge the gas from the interior of the processing container;
a transfer apparatus configured to carry the substrate into and out of the processing container; and
a controller configured to control the heater, the gas supplier, the gas discharger, and the transfer apparatus to perform the film formation method defined in claim 8.
